(19) United States
(12) Patent Application Publication
(10) Pub. No.: US 2026/0075820 A1
(43) Pub. Date: Mar. 12, 2026

(54) ELECTROCHEMICAL MEMORY DEVICE AND DRIVING METHOD THEREOF

(71) Applicant: Samsung Electronics Co., Ltd., Suwon-si (KR)

(72) Inventors: Moonil JUNG, Suwon-si (KR); Sangwook KIM, Suwon-si (KR); Yumin KIM, Suwon-si (KR)

(73) Assignee: Samsung Electronics Co., Ltd., Suwon-si (KR)

(21) Appl. No.: 19/076,636

(22) Filed: Mar. 11, 2025

(30) Foreign Application Priority Data
Sep. 10, 2024 (KR) 10-2024-0123395

(51) Int. Cl. H10B 43/27; G11C 16/14; G11C 16/26; H10B 43/10; H10B 43/35; H10D 62/80

(52) U.S. Cl. CPC H10B 43/27; G11C 16/14; G11C 16/26; H10B 43/10; H10B 43/35; H10D 62/875

(57) ABSTRACT

Provided is an electrochemical memory device including a channel layer extending in a vertical direction, the channel layer including a semiconductor oxide, a gate electrode surrounding at least a portion of a side surface of the channel layer, a reservoir layer between the channel layer and the gate electrode, and a gate oxide layer between the gate electrode and the reservoir layer, and wherein the channel layer includes a first channel layer and a second channel layer, the second channel layer spaced farther apart from the gate electrode than the first channel layer, and an oxygen dissociation energy of the first channel layer may be lower than an oxygen dissociation energy of the second channel layer.

### CROSS-REFERENCE TO RELATED APPLICATIONS

This application claims the benefit of Korean Patent Application No. 10-2024-0123395, filed on Sep. 10, 2024, in the Korean Intellectual Property Office, the disclosure of which is incorporated herein by reference in its entirety.

### BACKGROUND

### 1. Field of the Invention

Example embodiments relate to an electrochemical memory device and a driving method thereof.

### 2. Description of the Related Art

The manufacturing technology of NAND flash memory devices is developing to improve integration density, operating speed, and/or yield of semiconductor memory devices. For higher integration of semiconductor memory devices, a vertical NAND (VNAND) flash memory device may be advantageous.

The NAND flash memory devices including the VNAND flash memory device implement a memory function through a charge trap flash (CTF) manner for applying voltage to a gate electrode and moving electrons present in a channel layer to a trap layer by a tunneling effect. However, in the CTF manner, the voltage to be applied to a word line is relatively high, which may lead to inter-cell interference and thus has limitations to reducing the height between unit cells.

An alternative to the CTF manner includes an electrochemical random-access memory (ECRAM) device, which implements a memory function by a manner of applying voltage to a gate electrode such that ions present in a channel layer move and thereby changing the electrical conductivity of the channel layer.

### SUMMARY

An aspect provides an electrochemical memory device and a driving method of the electrochemical memory device configured to implement a memory function and improve integration density between unit cells even though relatively low voltage is applied to a gate electrode by adopting an operational principle of an ECRAM device to improve a CTF manner having difficulty in reducing the height between unit cells due to inter-cell interference.

Example embodiments are not limited to the technical features described above, and other unstated technical features may be made apparent to those skilled in the art from the following description.

According to an aspect, there is provided an electrochemical memory device including a channel layer extending in a vertical direction, the channel layer including a semiconductor oxide, a gate electrode surrounding at least a portion of a side surface of the channel layer, a reservoir layer between the channel layer and the gate electrode, and a gate oxide layer between the gate electrode and the reservoir layer, and wherein the channel layer may include a first channel layer and a second channel layer, the second channel layer spaced farther apart from the gate electrode than the first channel layer, and an oxygen dissociation energy of the first channel layer may be lower than an oxygen dissociation energy of the second channel layer.

According to another aspect, there is provided an electrochemical memory device including a channel layer extending in a vertical direction, the channel layer including a semiconductor oxide, a gate electrode surrounding at least a portion of a sidewall of the channel layer, a reservoir layer between the channel layer and the gate electrode, and a gate oxide layer between the gate electrode and the reservoir layer, and the channel layer may include a first area adjacent to the gate electrode and a second area spaced apart from the gate electrode, and an oxygen dissociation energy of the first area may be lower than an oxygen dissociation energy of the second area.

According to another aspect, there is provided a driving method of an electrochemical memory device, the electrochemical memory device comprising a channel layer extending in a vertical direction and including a semiconductor oxide, a gate electrode surrounding at least a portion of a side surface of the channel layer, a reservoir layer between the channel layer and the gate electrode, and a gate oxide layer between the gate electrode and the reservoir layer, the driving method including, performing a write or a read operation by exchanging oxygen ions between the channel layer and the reservoir layer by applying a voltage to the gate electrode such that oxygen vacancies in one of the channel layer and the reservoir layer increase and the oxygen vacancies in a remainder of the channel layer and the reservoir layer decrease, and such that an electrical conductivity of the channel layer changes compared to before the voltage is applied to the gate electrode.

Additional aspects of example embodiments will be set forth in part in the description which follows and, in part, will be apparent from the description.

According to example embodiments of the present disclosure, an electrochemical memory device and a driving method of the electrochemical memory device are provided that are configured to implement a memory function and to improve integration density between unit cells even though relatively low voltage is applied to a gate electrode.

The technical benefits achieved by example embodiments are not limited to those described above, and other technical benefits may be clearly understood by those skilled in the art from the following description.

### BRIEF DESCRIPTION OF THE FIGURES

The drawings of the present disclosure are shown according to example embodiments, and a ratio of width, length, or height (or thickness) of each element is to describe the present disclosure in detail, and the ratio may be different from the actual ratio. In addition, elements illustrated in the drawings may be exaggerated to describe the present disclosure in detail. Further, in a coordinate system shown in the drawings, each axis may be perpendicular to one another, and a direction pointed by an arrow may be+direction and a directly opposite direction (a direction turned by 180 degrees) to the direction pointed by the arrow may be—direction. Additionally, spatially relative terms, such as “upper,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly.

These and/or other aspects, features, and advantages of the invention will become apparent and more readily appreciated from the following description of example embodiments, taken in conjunction with the accompanying drawings of which:

FIG. 1 briefly illustrates at least a portion of an electrochemical memory device according to at least one example embodiment of the present disclosure;

FIG. 2 illustrates a cross-section taken along AA′ of FIG. 1;

FIG. 3 illustrates a cross-section taken along BB′ of FIG. 1;

FIG. 4 is an enlarged view of part P of FIG. 1;

FIG. 5 briefly illustrates at least a portion of an electrochemical memory device according to at least one example embodiment of the present disclosure;

FIG. 6 is an enlarged view of part Q of FIG. 5;

FIG. 7 briefly illustrates at least a portion of an electrochemical memory device according to at least one example embodiment of the present disclosure;

FIG. 8 is an enlarged view of part R of FIG. 7;

FIG. 9 briefly illustrates at least a portion of an electrochemical memory device according to at least one example embodiment of the present disclosure;

FIG. 10 illustrates a cross-section taken along CC′ of FIG. 9;

FIG. 11 is an enlarged view of part S of FIG. 9;

FIG. 12 briefly illustrates at least a portion of an electrochemical memory device according to at least one example embodiment of the present disclosure;

FIG. 13 illustrates a cross-section taken along DD′ of FIG. 12;

FIG. 14 is an enlarged view of part T of FIG. 12;

FIG. 15 is an enlarged view of part P of FIG. 1 and briefly illustrates at least a portion of an electrochemical memory device according to at least one example embodiment of the present disclosure;

FIG. 16 is an enlarged view of part S of FIG. 9 and briefly illustrates at least a portion of an electrochemical memory device according to at least one example embodiment of the present disclosure;

FIG. 17 is a graph briefly showing oxygen dissociation energy of a channel layer based on a distance from a gate electrode in at least one example embodiment of the present disclosure;

FIG. 18 is an enlarged view of part Q of FIG. 5 and briefly illustrates at least a portion of an electrochemical memory device according to at least one example embodiment of the present disclosure;

FIG. 19 is an enlarged view of part T of FIG. 12 and briefly illustrates at least a portion of an electrochemical memory device according to at least one example embodiment of the present disclosure;

FIG. 20 is a graph briefly showing oxygen dissociation energy of a channel layer based on a distance from a gate electrode in at least one example embodiment of the present disclosure; and

FIGS. 21 to 24 briefly illustrate at least a portion of an electrochemical memory device to describe a driving method of the electrochemical memory device according to at least one example embodiment of the present disclosure.

### DETAILED DESCRIPTION

Before describing the present disclosure in detail, the words and terminologies used in the specification and claims may not be construed as limited to common or dictionary meanings. More specifically, the words and terminologies are to be construed as having meanings and conceptions coinciding with the technical spirit of the present disclosure under a principle that the inventor(s) may appropriately define the conception of the terminologies to explain the invention in the optimum manner. The example embodiments described in the specification and the configurations illustrated in the drawings are no more than some example embodiments of the present disclosure and are not provided to fully cover the spirit of the present disclosure. Therefore, there may be various equivalents and modifications that may replace those when this application is filed. Additionally, when the terms “about” or “substantially” are used in this specification in connection with a numerical value and/or geometry, it is intended that the associated numerical value and/or geometry includes a manufacturing tolerance (e.g., ±10%) around the stated numerical value and/or geometry.

Like reference numerals or letters in each drawing attached to the specification may refer to components or elements performing substantially like functions. For convenience of description and understanding, the same reference numeral or letter may be used for description in different example embodiments. In other words, even though elements with the same reference numeral are illustrated in a plurality of drawings, all of the plurality of drawings may not represent a single example embodiment.

When an element is referred to as being “on” or “adjacent to” another element herein, it may be understood that the element may be in direct contact with or connected to another element or an intervening element may be present in between.

Further, when an element is referred to as being “above” another element herein, it may be understood that the element is present above another element based on a vertical direction, and it may be understood that the element may be in direct contact with or connected to another element or an intervening element may be present in between. Further, when an element is referred to as being “below” another element herein, it may be understood that the element is present below another element based on a vertical direction, and it may be understood that the element may be in direct contact with or connected to another element or an intervening element may be present in between.

In addition, when an element is referred to as being “directly on,” “contacting,” or “in contact with” another element herein, it may be understood that there are no intervening elements present in between. Other similar expressions describing position relationships between elements may also be similarly construed as above.

In the descriptions below, a singular expression includes a plural expression unless apparently otherwise defined by context. In the present disclosure, it may be understood that terms, such as “comprise or include”, are intended to indicate the presence of a feature, a number, a step, an operation, an element, a component, or a combination thereof which are described in the specification and not intended to previously exclude the possibility of the presence or addition of one or more other features, numbers, steps, operations, elements, components, or combinations thereof.

In addition, expressions such as upper side, upper surface, lower side, lower surface, side surface, front surface, and rear surface hereinafter are represented based on a direction illustrated in a drawing and may be represented otherwise when the direction of a corresponding object changes.

Further, terms including ordinal numbers such as “first” and “second” may be used to differentiate between elements in the specification and claims. These ordinal numbers may be used to differentiate identical or similar elements from each other, and the use of the ordinal numbers may not limit the meanings of terms. As at least one example, an element bonded with an ordinal number is not to be construed as the using order or arrangement order thereof is limited by the ordinal number. In some cases, each ordinal number may also be used by replacing each other.

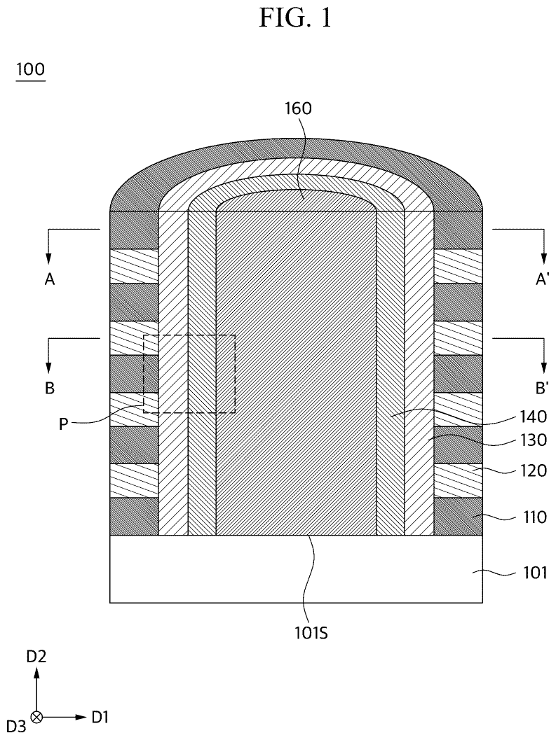

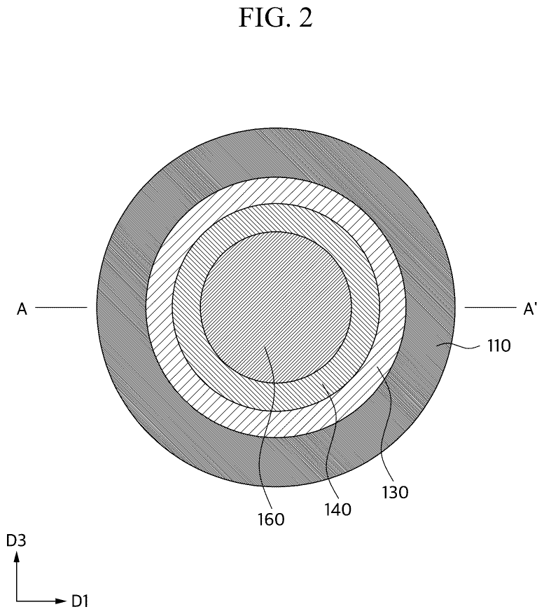

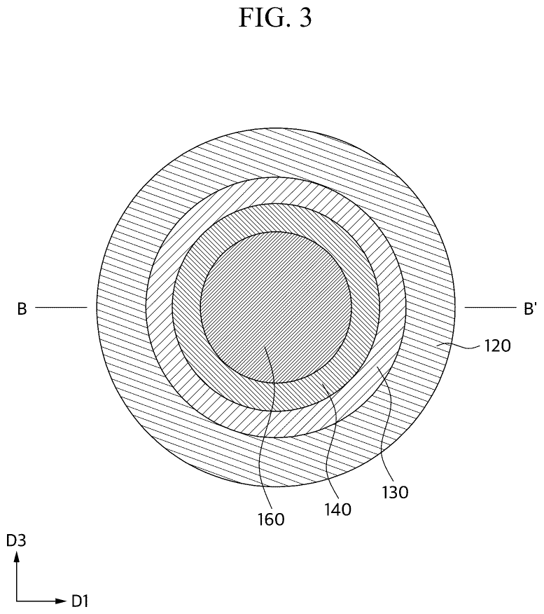

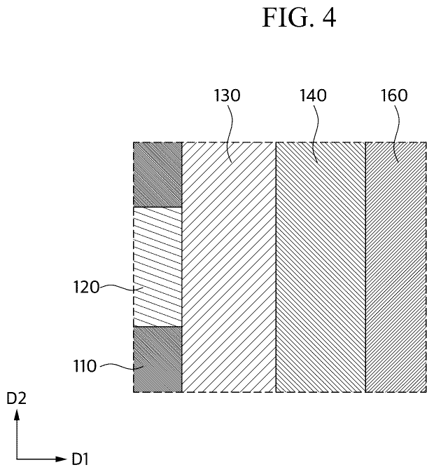

FIG. 1 briefly illustrates at least a portion of an electrochemical memory device 100 according to at least one example embodiment of the present disclosure. FIG. 2 illustrates a cross-section taken along AA′ of FIG. 1. FIG. 3 illustrates a cross-section taken along BB′ of FIG. 1. FIG. 4 is an enlarged view of part P of FIG. 1.

The electrochemical memory device 100 according to some example embodiments of the present disclosure may be, for example, a non-volatile memory device. In at least one example, the non-volatile memory device may be, for example, flash memory, read-only memory (ROM), etc., but is not limited thereto. In at least one example, the non-volatile memory device may be flash memory. In at least one example, the flash memory may be NAND flash memory and, specifically, vertical NAND flash memory. In at least one example, the electrochemical memory device 100 may be a vertical NAND flash memory device.

The electrochemical memory device 100 according to some to example embodiments of the present disclosure may include a substrate 101, at least one insulating layer 110, at least one gate electrode 120, a gate oxide layer 130, a reservoir layer 140, and a channel layer 160.

The substrate 101 may be, but is not limited to, a silicon semiconductor substrate, a plastic substrate, a glass substrate, a compound semiconductor substrate, a ceramic substrate, a silicon on insulator substrate (SOI), and/or the like. Though not illustrated, in at least one example, the substrate 101 may include at least one of an impurities area (e.g., by doping), an electronic device such as a transistor, a periphery circuit that selects and controls a memory cell, a combination therefore; and/or the like. In at least one example, the gate electrode 120, the gate oxide layer 130, the reservoir layer 140, and the channel layer 160 may be disposed on a surface 101S of the substrate 101.

The gate electrode 120 may be electrically connected to a word line (not illustrated). In at least one example, the gate electrode 120 may include a zero-band gap material and/or a material with a conductivity equivalent thereto. For example, the gate electrode 120 may include at least one of a metal material, a metal nitride, and/or a conductive silicon doped with impurities. In at least one example, the gate electrode 120 may include, but is not limited to, one or more of gold (Au), silver (Ag), aluminum (Al), titanium (Ti), indium (In), cadmium (Cd), copper (Cu), zinc (Zn), tantalum (Ta), molybdenum (Mo), tungsten (W), and/or the like.

The gate electrode 120 may surround at least a portion of the channel layer 160. In at least one example, the gate electrode 120 may be plural in number, and adjacent gate electrodes 120 may be spaced apart from each other based on a direction perpendicular to the surface 101S of the substrate 101 (e.g., the second direction D2).

The insulating layer 110 may include an insulating material. For example, the insulating material may include one or more selected of silicon oxide, silicon nitride, silicon oxynitride, and/or the like.

The insulating layer 110 may surround at least a portion of the channel layer 160. In at least one example, the insulating layer 110 may be plural in number, and adjacent insulating layers 110 may be spaced apart from each other based on a direction perpendicular to the surface 101S of the substrate 101 (e.g., the second direction D2). In at least one example, the insulating layer 110 may be disposed to fill space between the adjacent gate electrodes 120.

Referring to FIG. 1, the insulating layer 110 and the gate electrode 120 may have an alternately stacked structure, and the insulating layer 110 and the gate electrode 120 may be in contact with each other based on a direction perpendicular to the surface 101S of the substrate 101 (e.g., the second direction D2). Referring to FIG. 2, the insulating layer 110 may surround at least a portion of the channel layer 160. Referring to FIG. 3, the gate electrode 120 may surround at least a portion of the channel layer 160.

The channel layer 160 according to example embodiments of the present disclosure may be formed to extend in the second direction D2 intersecting a first direction D1 and a third direction D3, which are parallel to the surface 101S of the substrate. In at least one example, the channel layer 160 may be formed to extend in a direction (e.g., the second direction D2) intersecting the first direction D1 and being perpendicular to the surface 101S of the substrate.

The channel layer 160 may include a semiconductor oxide. In at least one example, the channel layer 160 may include oxide including one or more of tantalum (Ta), hafnium (Hf), aluminum (Al), zinc (Zn), tungsten (W), vanadium (V), titanium (Ti), niobium (Nb), silicon (Si), germanium (Ge), arsenic (As), tellurium (Te), antimony (Sb), gallium (Ga), indium (In), zirconium (Zr), tin (Sn), nickel (Ni), and/or the like as the semiconductor oxide. In at least one example, the channel layer 160 may include indium gallium zinc oxide (IGZO). However, not limited thereto, the channel layer 160 may include one or more of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), zinc oxide (ZnO), tungsten oxide (WO), indium gallium silicon oxide (IGSO), indium oxide (InO), tin oxide (SnO), titanium oxide (TiO), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and/or indium gallium silicon oxide (InGaSiO).

In at least one example, the channel layer 160 may include a semiconductor oxide of a nonstoichiometric state (e.g., in which a stoichiometric ratio between a metal element and oxygen is not satisfied). The nonstoichiometric state may indicate a state in which the octet rule or the 18-electron rule is not satisfied in an oxide.

The channel layer 160 may be spaced apart from the insulating layer 110 and the gate electrodes. The gate oxide layer 130 and the reservoir layer 140 may be disposed therebetween. The gate oxide layer 130 and the reservoir layer 140 are described in further detail below.

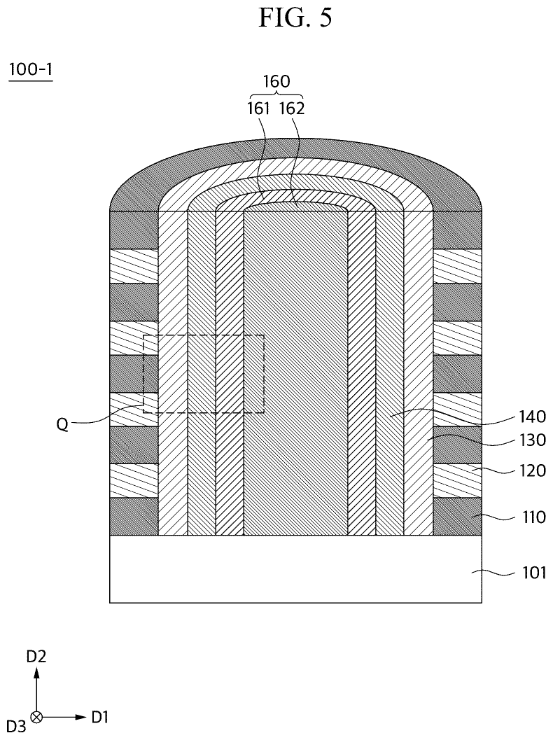

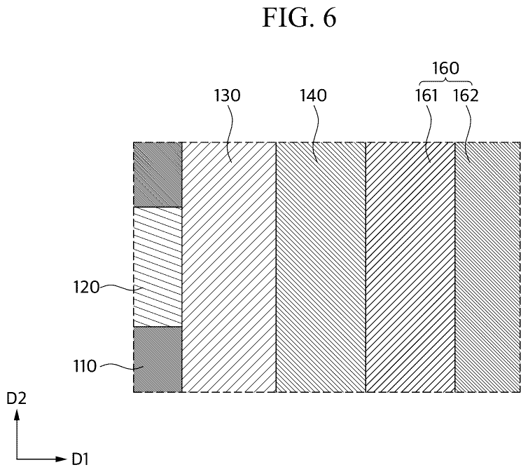

FIG. 5 briefly illustrates at least a portion of the electrochemical memory device 100-1 according to at least one example embodiment of the present disclosure. FIG. 6 is an enlarged view of part Q of FIG. 5.

The channel layer 160 according to example embodiments of the present disclosure may include a plurality of channel layers 161 and 162. In at least one example, the channel layer 160 may include the first channel layer 161 and the second channel layer 162 disposed to be spaced farther apart from the gate electrode 120 than the first channel layer 161.

In at least some example embodiments, the oxygen dissociation energy of the first channel layer 161 may be lower than the oxygen dissociation energy of the second channel layer 162. Accordingly, the electrochemical memory device 100-1 may have a threshold voltage (Vₜₕ) reduced when being driven and may implement a memory function even though relatively low voltage is applied to the gate electrode 120. In at least one example, the oxygen dissociation energy of the first channel layer 161 may be 95 percent (%) or less, 94% or less, 93% or less, 92% or less, 91% or less, and/or 90% or less of the oxygen dissociation energy of the second channel layer 162. In at least one example, the oxygen dissociation energy of the first channel layer 161 may be 50% or more, 55% or more, 60% or more, 65% or more, 70% or more, 75% or more, 80% or more, and/or 85% or more of the oxygen dissociation energy of the second channel layer 162.

The oxygen dissociation energy herein may be defined as a “standard bond enthalpy” between a specific element and oxygen, and the standard bond enthalpy may be defined as the energy required to break one mole of covalent bonds between the specific element of a gaseous state and oxygen and separate the specific element and oxygen based on the definition of the international union of pure and applied chemistry (IUPAC).

Each oxygen dissociation energy of the first channel layer 161 and the second channel layer 162 may be determined by a type of semiconductor oxide included in each of the channel layers 161 and 162. In at least one example, the first channel layer 161 may include a first semiconductor oxide, and the second channel layer 162 may include a second semiconductor oxide. In at least one example, the oxygen dissociation energy of the first semiconductor oxide may be lower than the oxygen dissociation energy of the second semiconductor oxide. In at least one example, the oxygen dissociation energy of the first semiconductor oxide may be 95% or less, 94% or less, 93% or less, 92% or less, 91% or less, and/or 90% or less of the oxygen dissociation energy of the second semiconductor oxide. In at least one example, the oxygen dissociation energy of the first semiconductor oxide may be 50% or more, 55% or more, 60% or more, 65% or more, 70% or more, 75% or more, 80% or more, and/or 85% or more of the oxygen dissociation energy of the second semiconductor oxide. In at least one example, the oxygen dissociation energy of the first channel layer 161 may be less than or equal to 400 kilojoules per mole (kJ/mol), 395 kJ/mol, and/or 390 kJ/mol.

In at least some embodiments, the oxygen concentration of the first channel layer 161 may be less than the oxygen concentration of the second channel layer 162. Specifically, in at least one example, the concentration of oxygen bonded with a metal element of the first semiconductor oxide included in the first channel layer 161 may be less than the concentration of oxygen bonded with a metal element of the second semiconductor oxide included in the second channel layer 162. Accordingly, as the oxygen dissociation energy of the first channel layer 161 is lower than the oxygen dissociation energy of the second channel layer 162, the electrochemical memory device 100 may have the threshold voltage (Vₜₕ) reduced when being driven and may implement a memory function even though relatively low voltage is applied to the gate electrode 120.

In at least one example, the first semiconductor oxide may have a metal element-oxygen bond. In at least one example, the second semiconductor oxide may have a metal element-oxygen bond. In at least one example, the first semiconductor oxide may include gallium (Ga). In at least one example, the first semiconductor oxide may include less than 33 atomic percent (at%) gallium (Ga) based on a total number of metal elements bonded with oxygen in the first semiconductor oxide. However, the examples are not limited thereto; and the first semiconductor oxide may include a metal element different from gallium (Ga). In at least one example, the second semiconductor oxide may include gallium (Ga). In at least one example, gallium (Ga) content based on a total number of metal elements bonded with oxygen in the second semiconductor oxide may be higher than gallium (Ga) content based on a total number of metal elements bonded with oxygen in the first semiconductor oxide. In this specification, not including a component refers to not including substantially and not including the corresponding component intentionally, and not including substantially may include including inevitably due to natural presence or diffusion during processes. In at least one example, the first semiconductor oxide may include indium (In). In at least one example, the first semiconductor oxide may include less than 33 at% indium (In) based on a total number of metal elements bonded with oxygen in the first semiconductor oxide. In at least one example, the second semiconductor oxide may include indium (In). In at least one example, indium (In) content based on a total number of metal elements bonded with oxygen in the second semiconductor oxide may be lower than indium (In) content based on a total number of metal elements bonded with oxygen in the first semiconductor oxide. Alternatively, in at least one example, the second semiconductor oxide may not include indium (In).

In at least one example, the first semiconductor oxide may include one or more of IGZO, InO, ZnO, and/or InZnO, and the second semiconductor oxide may include IGZO. In at least one example, the first semiconductor oxide may include InO, and the second semiconductor oxide may include IGZO. In other examples, each of the first semiconductor oxide and the second semiconductor oxide may include indium (In), gallium (Ga), and zinc (Zn), and the element content thereof may be determined independently of each other. For example, the first semiconductor oxide may have a ratio of the number of elements within the first semiconductor oxide of indium: gallium: zinc=3:2:1, and the second semiconductor oxide may have a ratio of the number of elements within the second semiconductor oxide of indium: gallium: zinc=1:1:1. However, this is merely an example, and the present disclosure is not limited thereto.

In the channel layer 160 according to some example embodiments of the present disclosure, a band gap of the first channel layer 161 may be smaller than a band gap of the second channel layer 162. In at least one example, the band gap of the first channel layer 161 may be 95% or less, 94% or less, 93% or less, 92% or less, 91% or less, and/or 90% or less of the band gap of the second channel layer 162. In at least one example, the band gap of the first channel layer 161 may be 50% or more, 55% or more, 60% or more, 65% or more, 70% or more, 75% or more, 80% or more, and/or 85% or more of the band gap of the second channel layer 162. Accordingly, the electrochemical memory device 100 may have the threshold voltage (Vₜₕ) reduced when being driven and may implement a memory function even though relatively low voltage is applied to the gate electrode 120. In at least one example, each band gap of the first channel layer 161 and the second channel layer 162 may be determined by a type of semiconductor oxide included in each of the channel layers 161 and 162.

In the channel layer 160 according to some example embodiments of the present disclosure, the crystallinity degree of the first channel layer 161 may be less than the crystallinity degree of the second channel layer 162. For the crystallinity degree herein, a widely known measurement manner through Bragg's law using X-ray diffraction (XRD) may be utilized. Accordingly, the electrochemical memory device 100 may have the threshold voltage (Vₜₕ) reduced when being driven and may implement a memory function even though relatively low voltage is applied to the gate electrode 120.

In the channel layer 160 according to some example embodiments of the present disclosure, the first channel layer 161 may include a halogen element. In at least one example, the halogen element may be, for example, one or more of fluorine (F), chlorine (Cl), bromine (Br), and iodine (I). In at least one example, when the first channel layer 161 includes fluorine (F), fluorine concentration may be less than or equal to 2×10¹⁴ per square centimeter (cm⁻²). In at least one example, the second channel layer 162 may include a halogen element, and the concentration of the halogen element included in the first channel layer 161 may be less than the concentration of the halogen element included in the second channel layer 162. Here, the second channel layer 162 may not include a halogen element. Accordingly, the thermal stability of the electrochemical memory device 100 may be secured while ions move smoothly.

The thickness of the channel layer 160 according to some example embodiments of the present disclosure is not particularly limited but may be 20 nanometers (nm) or less, 15 nm or less, and/or 10 nm or less. In at least one example, the thickness of the channel layer 160 may be greater than or equal to a minimum thickness that may be deposited in the atomic layer deposition (ALD) manner. In at least one example, the thickness of the channel layer 160 may indicate a length based on a direction parallel to the surface 101s of the substrate 101 (e.g., the first direction D1).

In some example embodiments, the thickness of the first channel layer 161 may be equal to or thinner than the thickness of the second channel layer 162. In at least one example, the thickness of the first channel layer 161 may be 50% or less, 45% or less, 40% or less, 35% or less, 30% or less, and/or 25% or less of the thickness of the second channel layer 162.

Referring to FIG. 1 and FIG. 5, the reservoir layer 140 according to example embodiments of the present disclosure may be disposed between the channel layer 160 and the gate electrode 120. In at least one example, the reservoir layer 140 is configured to have an increase or a decrease in oxygen vacancies according to a voltage applied to the gate electrode 120. In at least one example, when voltage is applied to the gate electrode 120, the reservoir layer 140 may have an increase or a decrease in oxygen vacancies in a direction opposite to the channel layer 160. In at least one example, when voltage is applied to the gate electrode 120, the oxygen vacancies of the reservoir layer 140 may decrease while the oxygen vacancies of the channel layer 160 increase, and the oxygen vacancies of the reservoir layer 140 may increase while the oxygen vacancies of the channel layer 160 decrease. In at least one example, when voltage is applied to the gate electrode 120, oxygen ions may move between the channel layer 160 and the reservoir layer 140 and thus each of the oxygen vacancies of the channel layer 160 and the reservoir layer 140 may increase or decrease, through which the electrical conductivity of the channel layer 160 may change. As such, the channel layer 160 and the reservoir layer 140 may also be referred to as exchanging oxygen ions.

The reservoir layer 140 according to example embodiments of the present disclosure may include a material with superior ion storage capacity, e.g., compared to the channel layer 160. The reservoir layer 140 may include an oxide with a metal element-oxygen bond. In at least one example, the oxide with the metal element-oxygen bond included in the reservoir layer 140 may be, but is not limited to, an oxide including one or more of tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), nickel (Ni), and/or the like. In at least one example, the oxide with the metal element-oxygen bond included in the reservoir layer 140 may include one or more of a single metal oxide having one metal element selected from the metal element group described above bonded with oxygen and a complex metal oxide having two or more metal elements selected from the metal element group described above bonded with oxygen. In at least one example, the oxide with the metal element-oxygen bond included in the reservoir layer 140 may include hafnium oxide.

In at least one example, the reservoir layer 140 may include a metal oxide of a nonstoichiometric state in which a stoichiometric ratio between a metal element (Me) and oxygen (O) is not satisfied. For example, when a stoichiometric ratio between the metal element (Me) and oxygen (O) is Me:O=1:2, the reservoir layer 140 may include a metal oxide of MeO₂₋ₓ (0<x<2). For example, the reservoir layer 140 may include HfO₂₋ₓ (0<x<2). Specifically, x may be greater than or equal to 0.01 and less than or equal to 1.0. In at least some embodiments, the metal oxide of the reservoir layer 140 have insulative or semiconductive properties.

The thickness of the reservoir layer 140 according to example embodiments of the present disclosure is not particularly limited but may be 20 nm or less, 15 nm or less, and/or 10 nm or less. In at least one example, the thickness of the reservoir layer 140 may be greater than or equal to a minimum thickness that may be deposited in the atomic layer deposition (ALD) manner. In at least one example, the thickness of the reservoir layer 140 may indicate a length based on the first direction D1.

In at least one example, when a positive voltage is applied to the gate electrode 120, the reservoir layer 140 may have a decrease in oxygen vacancies (Ov) and the channel layer 160 may have an increase in oxygen vacancies (Ov). In at least one example, when a negative voltage is applied to the gate electrode 120, the reservoir layer 140 may have an increase in oxygen vacancies (Ov) and the channel layer 160 may have a decrease in oxygen vacancies (Ov). In this process, the electrical conductivity of the channel layer 160 may be changed. Detailed descriptions are below.

The oxygen dissociation energy of the reservoir layer 140 according to example embodiments of the present disclosure may be greater than the oxygen dissociation energy of the channel layer 160. In at least one example, the oxygen dissociation energy of the reservoir layer 140 may be greater than the oxygen dissociation energy of the second channel layer 162. Accordingly, oxygen ions may move more smoothly between the reservoir layer 140 and the channel layer 160.

The gate oxide layer 130 according to example embodiments of the present disclosure may be disposed between the gate electrode 120 and the reservoir layer 140. In at least one example, the oxygen dissociation energy of the gate oxide layer 130 may be greater than the oxygen dissociation energy of the channel layer 160. In at least one example, the oxygen dissociation energy of the gate oxide layer 130 may be greater than the oxygen dissociation energy of the second channel layer 162. Further, in at least one example, the oxygen dissociation energy of the gate oxide layer 130 may be greater than the oxygen dissociation energy of the reservoir layer 140. Accordingly, oxygen ions may move more smoothly between the reservoir layer 140 and the channel layer 160, and oxygen ions present in the channel layer 160 may not be transferred to the gate electrode 120.

In at least one example, the gate oxide layer 130 may include an oxide with a metal element-oxygen bond. In at least one example, the oxide with the metal element-oxygen bond included in the gate oxide layer 130 may be selected as a material with insulative properties and with greater oxygen dissociation energy than the oxide with the metal element-oxygen bond included in the reservoir layer 140.

In at least one example, the oxide with the metal element-oxygen bond included in the gate oxide layer 130 may be, but is not limited to, an oxide including one or more of tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni). In at least one example, the oxide with the metal element-oxygen bond included in the gate oxide layer 130 may include one or more of a single metal oxide having one metal element selected from the metal element group described above bonded with oxygen and a complex metal oxide having two or more metal elements selected from the metal element group described above bonded with oxygen. In at least one example, the gate oxide layer 130 may include one or more of aluminum oxide and tin oxide.

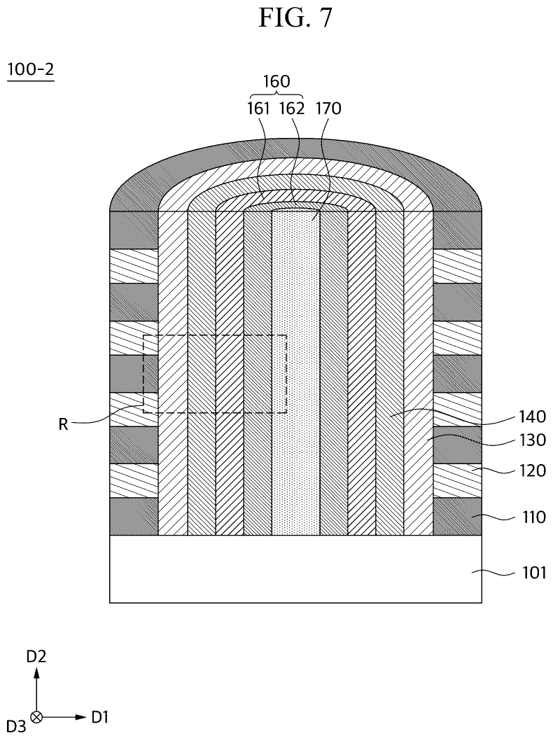

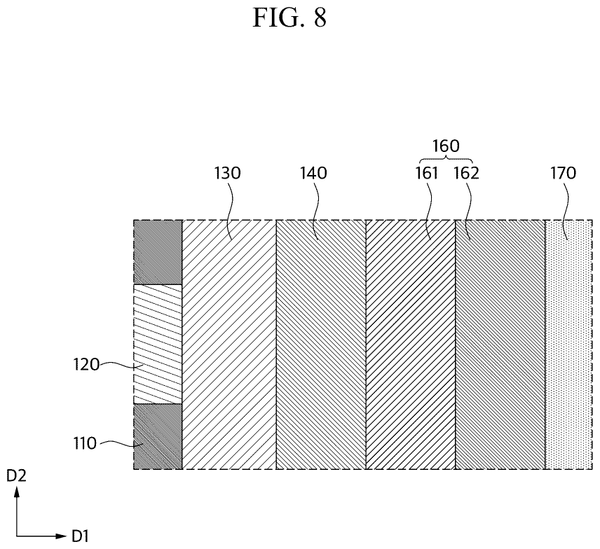

FIG. 7 briefly illustrates at least a portion of the electrochemical memory device 100-2 according to at least one example embodiment of the present disclosure. FIG. 8 is an enlarged view of part R of FIG. 7.

The electrochemical memory device 100-2 according to some example embodiments of the present disclosure may include a filling layer 170 surrounded by the channel layer 160 and/or the channel layers 161 and 162. In at least one example, the filling layer 170 may include an insulating material, and the insulating material included in the filling layer 170 may include, for example, one or more of air, silicon oxide, silicon nitride, silicon oxynitride, etc.

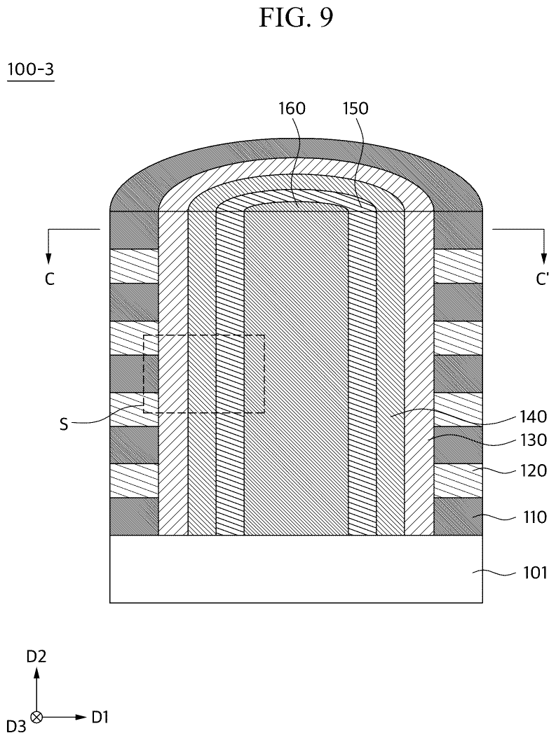

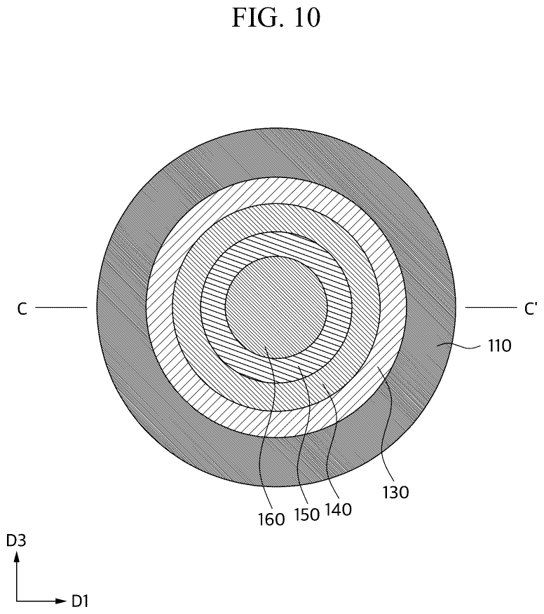

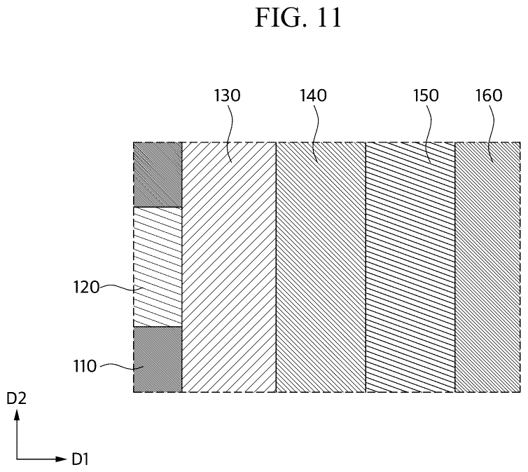

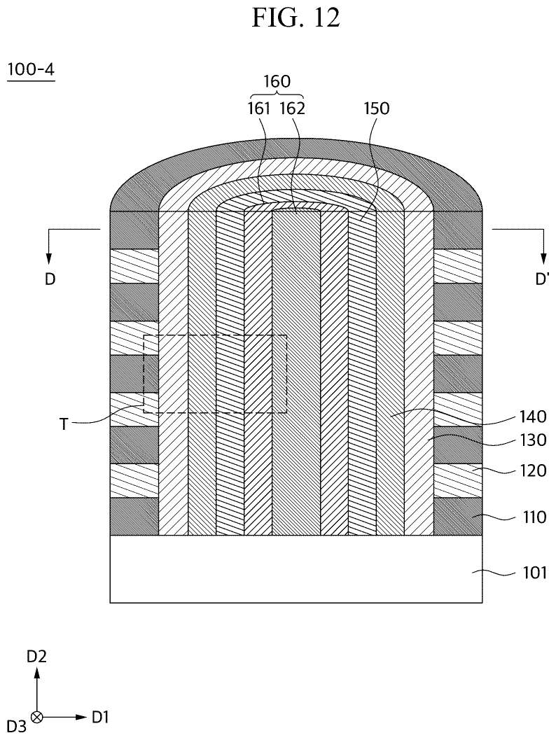

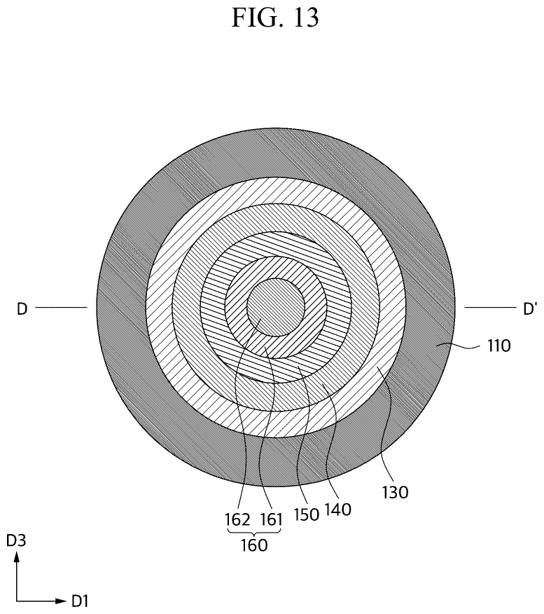

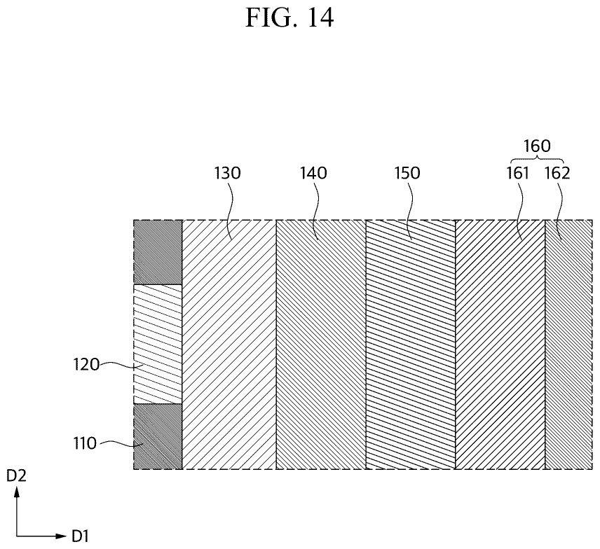

FIG. 9 briefly illustrates at least a portion of the electrochemical memory device 100-3 according to at least one example embodiment of the present disclosure. FIG. 10 illustrates a cross-section taken along CC′ of FIG. 9. FIG. 11 is an enlarged view of part S of FIG. 9. FIG. 12 briefly illustrates at least a portion of the electrochemical memory device 100 according to at least one example embodiment of the present disclosure. FIG. 13 illustrates a cross-section taken along DD′ of FIG. 12. FIG. 14 is an enlarged view of part T of FIG. 12. Descriptions with reference to FIGS. 9 to 14 may refer to the above description unless indicated otherwise.

The electrochemical memory devices 100-3 and 100-4, according to some example embodiments of the present disclosure, may include an electrolyte layer 150 disposed between the channel layer 160 and the reservoir layer 140. In at least one example, the electrolyte layer 150 may be configured to allow oxygen ions to move smoothly between the channel layer 160 and the reservoir layer 140 according to a voltage applied to the gate electrode 120. In other words, the electrolyte layer 150 may pass oxygen ions transferred from the reservoir layer 140 to the channel layer 160 or transferred from the channel layer 160 to the reservoir layer 140 depending on a voltage applied to the gate electrode 120. In at least one example, the electrolyte layer 150 may allow oxygen ions to move smoothly between the channel layer 160 and the reservoir layer 140 and may change the electrical conductivity of the channel layer 160 based on the movement of the oxygen ions and increasing and decreasing degrees of oxygen vacancies. In at least one example, the electrolyte layer 150 may include a material with superior ion conductivity compared to, e.g., the channel layer 160, the reservoir layer 140, and/or the interface therebetween.

In at least one example, the oxygen dissociation energy of the electrolyte layer 150 may be greater than the oxygen dissociation energy of the channel layer 160. In at least one example, the oxygen dissociation energy of the electrolyte layer 150 may be greater than the oxygen dissociation energy of the second channel layer 162. In at least one example, the oxygen dissociation energy of the electrolyte layer 150 may be lower than the oxygen dissociation energy of the reservoir layer 140. Accordingly, the electrolyte layer 150 may allow oxygen ions to move smoothly between the reservoir layer 140 and the channel layer 160.

The electrolyte layer 150 may include an oxide with a metal element-oxygen bond. In at least one example, the oxide with the metal element-oxygen bond included in the electrolyte layer 150 may be selected as a material with lower oxygen dissociation energy than the oxide with the metal element-oxygen bond included in the reservoir layer 140.

In at least one example, the oxide with the metal element-oxygen bond included in the electrolyte layer 150 may be, but is not limited to, an oxide including one or more of tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni). In at least one example, the oxide with the metal element-oxygen bond included in the electrolyte layer 150 may include one or more of a single metal oxide having one metal element selected from the metal element group described above bonded with oxygen and a complex metal oxide having two or more metal elements selected from the metal element group described above bonded with oxygen. In at least one example, the oxide with the metal element-oxygen bond included in the electrolyte layer 150 may include hafnium oxide. In at least one example, the electrolyte layer 150 may include a metal oxide of a nonstoichiometric state in which a stoichiometric ratio between a metal element and oxygen is not satisfied. For example, when a stoichiometric ratio between metal (Me) and oxygen (O) is Me:O=1:2, the electrolyte layer 150 may include a metal oxide of MeO₂₋ₓ (0<x<2). For example, the electrolyte layer 150 may include HfO₂₋ₓ (0<x<2). Specifically, x may be greater than or equal to 0.01 and less than or equal to 1.0. The oxide of the electrolyte layer 150 may have insulative or semiconductive properties.

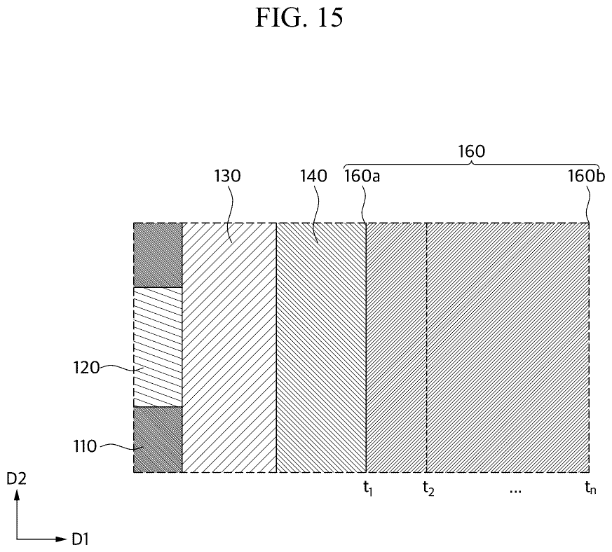

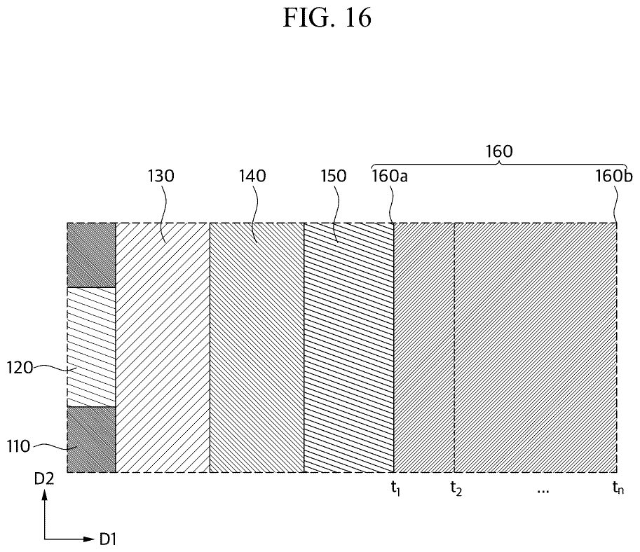

FIG. 15 is an enlarged view of part P of FIG. 1 and briefly illustrates at least a portion of the electrochemical memory device 100 according to at least one example embodiment of the present disclosure. FIG. 16 is an enlarged view of part S of FIG. 9 and briefly illustrates at least a portion of the electrochemical memory device 100-3 according to at least one example embodiment of the present disclosure. Descriptions with reference to FIGS. 15 and 16 may refer to the above description unless indicated otherwise.

The channel layer 160 according to some example embodiments of the present disclosure may be a single layer and may be divided into a plurality of areas 160a and 160b. In at least one example, the channel layer 160 may be divided into two or more areas that have different oxygen dissociation energies. In at least one example, the channel layer 160 may include the first area 160a most adjacent to the gate electrode 120 and the second area 160b spaced farthest apart from the gate electrode 120. In at least one example, a description of the first area 160a may be substantially similar to the description of the first channel layer 161 described, and a description of the second area 160b may be substantially similar to the description of the second channel layer 162. For example, in the channel layer 160, according to some example embodiments of the present disclosure, the oxygen dissociation energy of the first area 160a may be lower than the oxygen dissociation energy of the second area 160b. In at least one example, the channel layer 160 is not limited thereto and may be divided into n (n is 2 or more) areas based on the first direction D1.

In some example embodiments, since the oxygen dissociation energy of the first area 160a may be lower than the oxygen dissociation energy of the second area 160b, the electrochemical memory device 100 may have the threshold voltage (Vₜₕ) reduced when being driven and may implement a memory function even though relatively low voltage is applied to the gate electrode 120. In at least one example, the oxygen dissociation energy of the first area 160a may be 95% or less, 94% or less, 93% or less, 92% or less, 91% or less, and/or 90% or less of the oxygen dissociation energy of the second area 160b. In at least one example, the oxygen dissociation energy of the first area 160a may be 50% or more, 55% or more, 60% or more, 65% or more, 70% or more, 75% or more, 80% or more, and/or 85% or more of the oxygen dissociation energy of the second area 160b.

In the channel layer 160 according to some example embodiments of the present disclosure, the oxygen concentration of the first area 160a may be less than the oxygen concentration of the second area 160b. Specifically, in at least one example, the concentration of oxygen bonded with a metal element of a first semiconductor oxide included in the first area 160a may be less than the concentration of oxygen bonded with a metal element of a second semiconductor oxide included in the second area 160b. Accordingly, as the oxygen dissociation energy of the first area 160a is lower than the oxygen dissociation energy of the second area 160b, the electrochemical memory device 100 may have the threshold voltage (Vₜₕ) reduced when being driven and may implement a memory function even though relatively low voltage is applied to the gate electrode 120.

The channel layer 160 according to example embodiments of the present disclosure may include a semiconductor oxide with a metal element-oxygen bond. In at least one example, the semiconductor oxide included in the channel layer 160 may have a gallium (Ga)-oxygen (O) bond, and a ratio of the number of elements of gallium (Ga) bonded with oxygen in the first area 160a may be less than a ratio of the number of elements of gallium (Ga) bonded with oxygen in the second area 160b. In at least one example, the semiconductor oxide included in the channel layer 160 may have an indium (In)-oxygen (O) bond, and a ratio of the number of elements of indium (In) bonded with oxygen in the first area 160a may be greater than a ratio of the number of elements of indium (In) bonded with oxygen in the second area 160b.

In the channel layer 160 according to some example embodiments of the present disclosure, a band gap of the first area 160a may be smaller than a band gap of the second area 160b. In at least one example, the band gap of the first area 160a may be 95% or less, 94% or less, 93% or less, 92% or less, 91% or less, and/or 90% or less of the band gap of the second area 160b. In at least one example, the band gap of the first area 160a may be 50% or more, 55% or more, 60% or more, 65% or more, 70% or more, 75% or more, 80% or more, and/or 85% or more of the band gap of the second area 160b. Accordingly, the electrochemical memory device 100 may have the threshold voltage (Vₜₕ) reduced when being driven and may implement a memory function even though relatively low voltage is applied to the gate electrode 120.

In the channel layer 160 according to example embodiments of the present disclosure, the crystallinity degree of the first area 160a may be less than the crystallinity degree of the second area 160b. Accordingly, the electrochemical memory device 100 may have the threshold voltage (Vₜₕ) reduced when being driven and may implement a memory function even though relatively low voltage is applied to the gate electrode 120.

The channel layer 160 according to some example embodiments may include a halogen element. In at least one example, the halogen element may be, for example, one or more of fluorine (F), chlorine (Cl), bromine (Br), and/or iodine (I). In at least one example, when the channel layer 160 includes fluorine (F), fluorine concentration may be less than or equal to 2×10¹⁴/cm². In at least one example, a concentration of the halogen element included in the first area 160a may be less than a concentration of the halogen element included in the second area 160b. Here, the second area 160b may not include a halogen element. In at least some embodiments, an area between the first area 160a and the second area 160b may include a gradient of the halogen element. Accordingly, the thermal stability of the electrochemical memory device 100 may be secured while ions move smoothly.

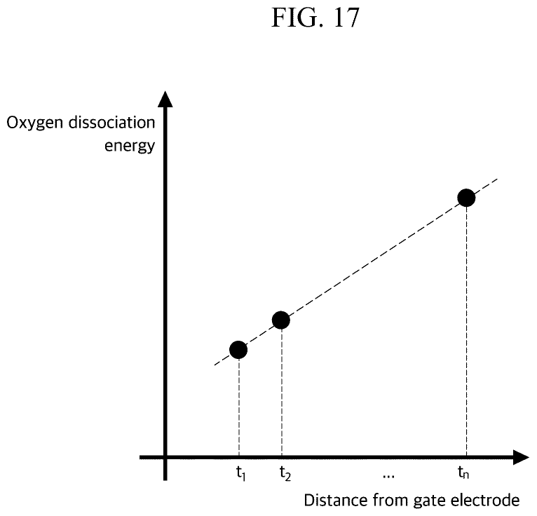

FIG. 17 is a graph briefly showing oxygen dissociation energy of the channel layer 160 based on a distance from the gate electrode 120 in at least one example embodiment of the present disclosure.

The channel layer 160 according to example embodiments of the present disclosure may have a gradual increase in oxygen dissociation energy from the first area 160a toward the second area 160b. Here, the gradual increase in oxygen dissociation energy is not particularly limited but may indicate a gradual increase in the form of linear function or quadratic function or higher or a stepwise increase. Referring to FIG. 17, when n (n is a natural number) areas are designated in the channel layer 160 and each area is represented as t ₁ to tₙ based on a distance from the gate electrode 120, the oxygen dissociation energy of area t₁ to tₙ may have a gradual increase as n increases.

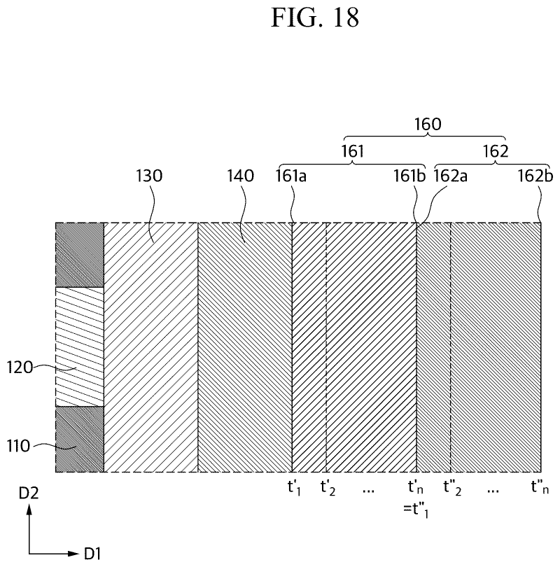

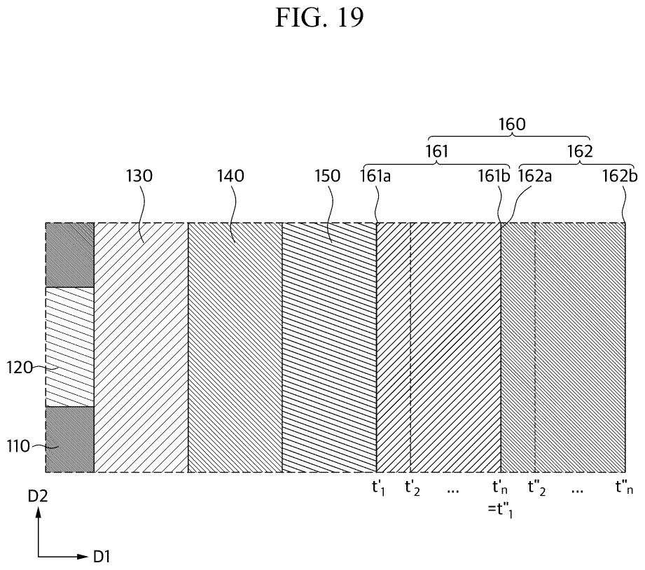

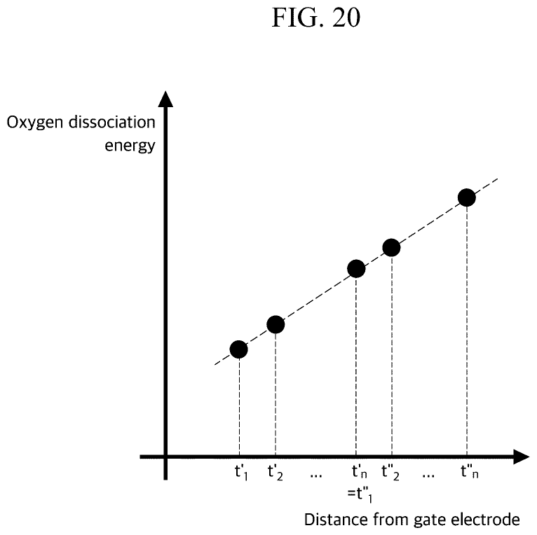

FIG. 18 is an enlarged view of part Q of FIG. 5 and briefly illustrates at least a portion of the electrochemical memory device 100 according to at least one example embodiment of the present disclosure. FIG. 19 is an enlarged view of part T of FIG. 12 and briefly illustrates at least a portion of the electrochemical memory device 100 according to at least one example embodiment of the present disclosure. FIG. 20 is a graph briefly showing oxygen dissociation energy of the channel layer 160 based on a distance from the gate electrode 120 in at least one example embodiment of the present disclosure.

Referring to FIGS. 18 and 19, in at least one example, the first channel layer 161 and the second channel layer 162 may be divided into two or more areas having different oxygen dissociation energies. In at least one example, the first channel layer 161 may include a first-first area 161a most adjacent to the gate electrode 120 and a first-second area 161b spaced farthest apart from the gate electrode 120. In at least one example, the second channel layer 162 may include a second-first area 162a most adjacent to the gate electrode 120 and a second-second area 162b spaced farthest apart from the gate electrode 120. Here, descriptions of the first-first area 161a and the second-first area 162a may be substantially similar to the description of the first area 160a described above unless indicated otherwise, and descriptions of the first-second area 161b and the second-second area 162b may be substantially similar to the description of the second area 160b described above unless indicated otherwise. In at least one example, the first channel layer 161 and the second channel layer 162 are not limited thereto and may be divided into n (n is 2 or more) areas based on the first direction D1. In at least one example, an interface between the first-second area 161b and the second-first area 162a may be indistinct, such that the first-second area 161b and the second-first area 162a are integrated.

The first channel layer 161 according to example embodiments of the present disclosure may have a gradual increase in oxygen dissociation energy from the first-first area 161a toward the first-second area 161b. In at least one example, the second channel layer 162 may have a gradual increase in oxygen dissociation energy from the second-first area 162a toward the second-second area 162b. Referring to FIG. 20, when n (n is any natural number) areas are designated arbitrarily in the first channel layer 161 and the second channel layer 162 each independently and each area is represented as t′₁ to t′ₙ and t″₁ to t″ₙ based on a distance from the gate electrode 120, the oxygen dissociation energy of area t′₁ to t′ₙ may have a gradual increase as n increases, and the oxygen dissociation energy of area t″₁ to t″ₙ may have a gradual increase as n increases. Further, in at least one example, when the first-second area 161b and the second-first area 162a are identical, the oxygen dissociation energy of the first-second area 161b and the oxygen dissociation energy of the second-first area 162a may be identical.

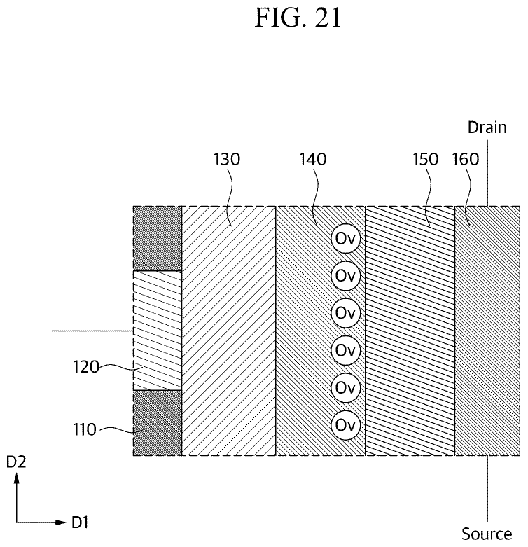

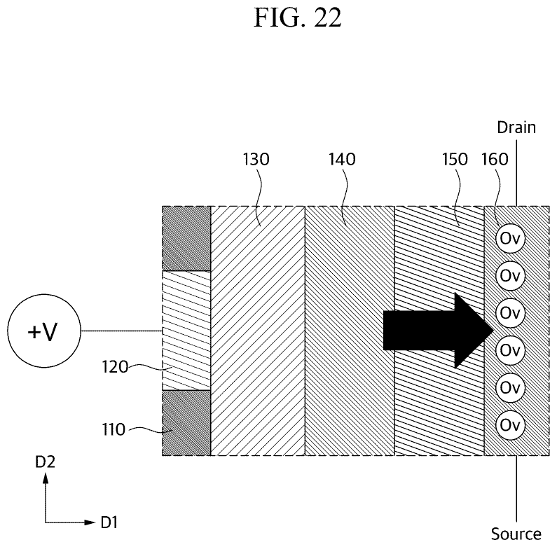

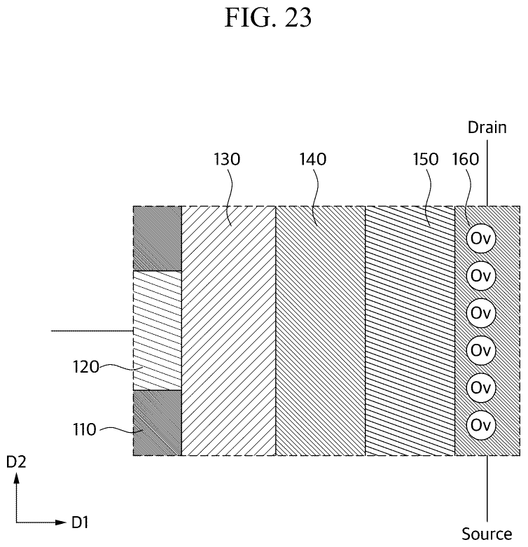

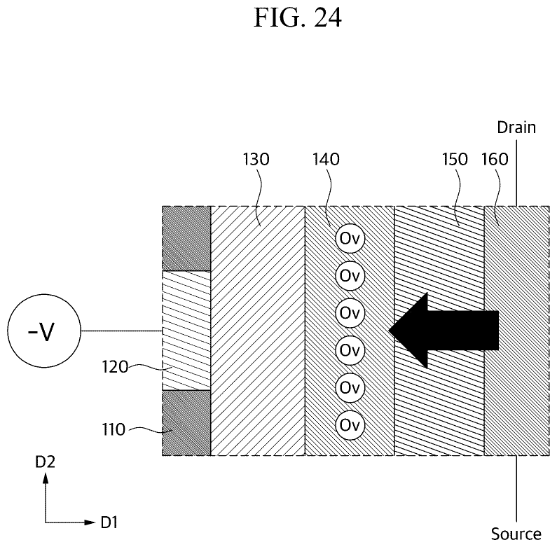

FIGS. 21 to 24 briefly illustrate at least a portion of the electrochemical memory device 100 to describe a driving method of the electrochemical memory device 100 according to at least one example embodiment of the present disclosure.

In the driving method of the electrochemical memory device 100 according to at least one example embodiment of the present disclosure, when voltage is applied to the gate electrode 120, oxygen ions may move between the channel layer 160 and the reservoir layer 140, which may lead to an increase or a decrease in the oxygen vacancies (Ov) of the channel layer 160 and the reservoir layer 140. Accordingly, the electrical conductivity of the channel layer 160 may change from the electrical conductivity of the channel layer 160 before voltage is applied to the gate electrode 120.

In at least one example, when voltage is applied to the gate electrode 120, the electrolyte layer 150 may pass oxygen ions smoothly so that the oxygen ions move from the channel layer 160 to the reservoir layer 140.

In at least one example, when voltage is applied to the gate electrode 120, the gate oxide layer 130 may allow oxygen ions to move smoothly between the reservoir layer 140 and the channel layer 160 and enable oxygen ions present in the reservoir layer 140 not to be transferred to the gate electrode 120.

In at least one example, the channel layer 160 may be electrically connected to a source and a drain. In at least one example, the source and the drain may each include a conductive material. In at least one example, the conductive material may include, for example, one or more of doped polysilicon, metal, conductive metal nitride, conductive metal silicide, conductive metal oxide, etc. In at least one example, the metal may include one or more of aluminum (Al), copper (Cu), titanium (Ti), tantalum (Ta), rubidium (Rb), tungsten (W), molybdenum (Mo), platinum (Pt), nickel (Ni), cobalt (Co), etc. In at least one example, the conductive metal nitride may include one or more selected from TiAl or TiAlN. In at least one example, the conductive metal silicide may include one or more of TiSi, TiSiN, TaSi, TaSiN, RuTiN, NiSi, and CoSi. In at least one example, the conductive metal oxide may include one or more selected from IrOx or RuOx.

In at least one example, in the driving method of the electrochemical memory device 100, as oxygen ions present in the reservoir layer 140 move to the channel layer 160 or oxygen ions present in the channel layer 160 move to the reservoir layer 140 when voltage is applied to the gate electrode 120, the oxygen vacancies (Ov) of the channel layer 160 and the reservoir layer 140 may increase or decrease. In other words, it may be presented that the oxygen vacancies (Ov) move in a direction opposite to a direction of oxygen ions moving. In this case, the electrical conductivity of the channel layer 160 may change compared to before voltage is applied to the gate electrode 120, and as the electrical conductivity of the channel layer 160 changes, the driving method of the electrochemical memory device 100 may include performing write (or program) or erase.

In at least one example, the driving method of the electrochemical memory device 100 may include performing a write operation (or writing) in which, when a positive voltage is applied to the gate electrode 120, the oxygen ions of the channel layer 160 move to the reservoir layer 140, and the oxygen vacancies (Ov) of the reservoir layer 140 move to the channel layer 160, and accordingly the oxygen vacancies (Ov) of the reservoir layer 140 decreases and the oxygen vacancies (Ov) of the channel layer 160 increases, and thus the electrical conductivity of the channel layer 160 increases. Here, the driving method of the electrochemical memory device 100 may include performing an erase operation (or erasing) in which, when a negative voltage changed from the positive voltage is applied to the gate electrode 120, the oxygen ions of the reservoir layer 140 move to the channel layer 160, the oxygen vacancies (Ov) of the channel layer 160 are returned to the reservoir layer 140, and accordingly the oxygen vacancies (Ov) of the reservoir layer 140 increases and the oxygen vacancies (Ov) of the channel layer 160 decreases, and thus the electrical conductivity of the channel layer 160 decreases.

In at least one example, the driving method of the electrochemical memory device 100 may include writing or erasing the threshold voltage (Vₜₕ) changes when voltage is applied to the gate electrode 120. In at least one example, the threshold voltage may change due to a change in the conductivity of the channel layer 160, and the threshold voltage may decrease when a positive voltage is applied to the gate electrode 120.

In at least one example, the driving method of the electrochemical memory device 100 may include performing a read operation (or reading) to identify the electrical conductivity (in other words, a state of data) of the channel layer 160 by applying voltage to the gate electrode 120. Here, the voltage applied to the gate electrode 120 may be a voltage low enough not to cause a movement of oxygen ions or oxygen vacancies (Ov). Further, in at least one example, the electrical conductivity (in other words, a state of data) of the channel layer 160 may change depending on a degree of oxygen ions or oxygen vacancies (Ov) included in the channel layer 160. The electrical conductivity of the channel layer 160 may be measured by the resistance through a current-voltage curve, through which read may be performed.

While example embodiments of the present disclosure are described above with reference to the accompanying drawings, the present disclosure is not limited to the example embodiments and may be implemented in various different forms, and it will be apparent to those of ordinary skill in the art to which the present disclosure pertains that other specific forms may be implemented without changing the technical spirit and essential features of the present disclosure. Therefore, the example embodiments described above are examples and not to be construed as limited.

What is claimed is:

1. An electrochemical memory device comprising:
a channel layer extending in a vertical direction, the channel layer including a semiconductor oxide;
a gate electrode surrounding at least a portion of a side surface of the channel layer;
a reservoir layer between the channel layer and the gate electrode; and
a gate oxide layer between the gate electrode and the reservoir layer,
wherein the channel layer includes a first channel layer and a second channel layer, the second channel layer spaced farther apart from the gate electrode than the first channel layer, and
wherein an oxygen dissociation energy of the first channel layer is lower than an oxygen dissociation energy of the second channel layer.

2. The electrochemical memory device of claim 1, wherein the channel layer and the reservoir layer are configured such that oxygen vacancies in one of the channel layer and the reservoir layer increase and oxygen vacancies in a remainder of the channel layer and the reservoir layer decrease as oxygen ions move between the channel layer and the reservoir layer when a voltage is applied to the gate electrode.

3. The electrochemical memory device of claim 1, wherein a band gap of the first channel layer is smaller than a band gap of the second channel layer.

4. The electrochemical memory device of claim 1, wherein an oxygen concentration of the first channel layer is less than an oxygen concentration of the second channel layer.

5. The electrochemical memory device of claim 1, wherein a crystallinity degree of the first channel layer is less than a crystallinity degree of the second channel layer.

6. The electrochemical memory device of claim 1, wherein the first channel layer includes a first semiconductor oxide with a metal element-oxygen bond,
wherein the second channel layer includes a second semiconductor oxide with a metal element-oxygen bond, and
wherein an atomic percentage (at%) of gallium (Ga) in the first semiconductor oxide satisfies 0 at%<Ga≤33 at% based on a total number of metal elements bonded with oxygen in the first channel layer.

7. The electrochemical memory device of claim 6, wherein the second semiconductor oxide includes gallium (Ga), and
wherein an atomic percentage of gallium (Ga), based on a total number of metal elements bonded with oxygen in the second semiconductor oxide, is higher than the atomic percentage of gallium (Ga) in the first semiconductor oxide.

8. The electrochemical memory device of claim 6, wherein the first semiconductor oxide and the second semiconductor oxide include indium (In),
wherein an atomic percentage of indium (In) in the second semiconductor oxide is lower than an atomic percentage of indium (In) in the first semiconductor oxide, and
wherein the atomic percentage of indium (In) in the second semiconductor oxide is based on a total number of metal elements bonded with oxygen in the second semiconductor oxide, and the atomic percentage of indium (In) in the first semiconductor oxide is based on the total number of metal elements bonded with oxygen in the first semiconductor oxide.

9. The electrochemical memory device of claim 1, wherein the channel layer includes a halogen element, and
wherein a halogen element concentration of the first channel layer is less than a halogen element concentration of the second channel layer.

10. The electrochemical memory device of claim 1, wherein an oxygen dissociation energy of the gate oxide layer is greater than the oxygen dissociation energy of the second channel layer.

11. The electrochemical memory device of claim 1, wherein an oxygen dissociation energy of the reservoir layer is greater than the oxygen dissociation energy of the second channel layer.

12. The electrochemical memory device of claim 1, further comprising:
an electrolyte layer between the channel layer and the reservoir layer,
wherein the electrolyte layer is configured to pass oxygen ions between the channel layer and the reservoir layer when a voltage is applied to the gate electrode.

13. The electrochemical memory device of claim 12, wherein an oxygen dissociation energy of the electrolyte layer is greater than the oxygen dissociation energy of the second channel layer.

14. The electrochemical memory device of claim 1, wherein a thickness of the first channel layer is equal to or less than a thickness of the second channel layer.

15. An electrochemical memory device comprising:
a channel layer extending in a vertical direction, the channel layer including a semiconductor oxide;
a gate electrode surrounding at least a portion of a side surface of the channel layer;
a reservoir layer between the channel layer and the gate electrode; and
a gate oxide layer between the gate electrode and the reservoir layer,
wherein the channel layer includes a first area adjacent to the gate electrode and a second area spaced apart from the gate electrode, and
wherein an oxygen dissociation energy of the first area is lower than an oxygen dissociation energy of the second area.

16. The electrochemical memory device of claim 15, wherein an oxygen dissociation energy of the channel layer gradual increases from the first area towards the second area.

17. A driving method of an electrochemical memory device, the electrochemical memory device comprising a channel layer extending in a vertical direction and including a semiconductor oxide, a gate electrode surrounding at least a portion of a side surface of the channel layer, a reservoir layer between the channel layer and the gate electrode, and a gate oxide layer between the gate electrode and the reservoir layer, the driving method comprising:
performing a write or a read operation by exchanging oxygen ions between the channel layer and the reservoir layer by applying a voltage to the gate electrode such that oxygen vacancies in one of the channel layer and the reservoir layer increase and the oxygen vacancies in a remainder of the channel layer and the reservoir layer decrease, and such that an electrical conductivity of the channel layer changes compared to before the voltage is applied to the gate electrode.

18. The driving method of claim 17, wherein, the applying the voltage the gate electrode includes a change in a threshold voltage (Vₜₕ) of the channel layer.

19. The driving method of claim 17, wherein
the write operation includes applying a positive voltage to the gate electrode so that the reservoir layer has a decrease in the oxygen vacancies and the channel layer has an increase in the oxygen vacancies and the electrical conductivity of the channel layer increases compared to before the positive voltage is applied to the gate electrode, and
the erase operation includes applying a negative voltage to the gate electrode so that the reservoir layer has an increase in the oxygen vacancies and the channel layer has a decrease in the oxygen vacancies and the electrical conductivity of the channel layer decreases compared to before the negative voltage is applied to the gate electrode.

20. The driving method of claim 17, further comprising:
performing a read operation, the read operation including applying a read voltage to the gate electrode and identifying the electrical conductivity of the channel layer.
